(19) United States
(12) Patent Application Publication
(10) Pub. No.: US 2005/0270746 A1
(43) Pub. Date: Dec. 8, 2005

(54) Insulating structure having combined insulating and heat spreading capabilities

(76) Inventor: Bradley E. Reis, Landenberg, PA (US)

Correspondence Address: GORE ENTERPRISE HOLDINGS, INC., 551 PAPER MILL ROAD, P. O. BOX 9206, NEWARK, DE, 19714-9206, US

(21) Appl. No.: 10/861,321

(22) Filed: Jun. 4, 2004

(51) Int. Cl. H05K 7/20

(52) U.S. Cl. 361/708

(57) ABSTRACT

The present invention provides an insulating structure comprising an insulating material and a heat spreading material. The invention further provides a portable electronic device comprising at least one heat generating component, an enclosure, and an insulating structure, wherein the insulating structure comprises an insulating material and a heat spreading material.

### BACKGROUND OF THE INVENTION

In portable electronic devices such as notebook computers, PDA's (personal digital assistants), cell phones and the like, as the size of the physical envelope or enclosure of the device decreases, and/or functionality of the device increases, thermal management becomes a challenge. Increased functionality often generates more heat in certain components of electronic devices. Reduced size of the physical envelope of the device positions heat-generating components in closer proximity to outer enclosures, increasing the ease at which the components conduct heat to the surfaces of outer enclosures. Outer enclosure surfaces that are in direct contact with a user may thus become uncomfortably hot, particularly in locations directly adjacent heat generating components. These are often called hot-spots.

One way that is currently used to deal with such hot-spots is to use a heat spreading material, which serves to spread the heat generated by heat-generating components over a larger area. This generally results in a reduction of the temperature measured at the hot-spot, and a slight increase in temperature measured elsewhere. The desirable net effect is a more even distribution of temperature. In addition to being effective at spreading heat (i.e., being highly thermally conductive in the XY-direction), however, heat spreading materials are also highly thermally conductive in the Z-direction (i.e. in a direction perpendicular to the XY-direction). This has the unintended and undesired effect of more readily transferring heat towards outer enclosure surfaces, which are often in direct contact with a user.

There is currently no known way to spread the heat generated at such hot-spots in portable electronic devices without readily transferring the heat to the outer enclosure surfaces. A better structure is thus desired that more significantly inhibits or delays the transfer of heat in the Z-direction, while simultaneously effectively spreading heat in the XY-direction.

### SUMMARY OF THE INVENTION

The present invention provides an insulating structure comprising an insulating material and a heat spreading material.

In another aspect, the invention provides a portable electronic device comprising at least one heat generating component, an enclosure surface adjacent to the at least one heat generating component, and an insulating structure disposed between the at least one heat generating component and the enclosure surface; wherein the insulating structure comprises an insulating material and a heat spreading material.

In yet another aspect, the invention provides a method of reducing heat at hot-spots of a portable electronic device comprising the steps of providing a portable electronic device having at least one heat generating component and an enclosure having a surface, and placing an insulating structure comprising an insulating material and a heat spreading material between the heat generating component and the enclosure, thereby preventing or delaying the transfer of heat from the heat generating component to at least a portion of the enclosure surface.

### DESCRIPTION OF THE DRAWINGS

FIG. 1 is a perspective view of an insulating structure according to an exemplary embodiment of the present invention.

FIG. 2 is a perspective view of an insulating structure according to another exemplary embodiment of the present invention.

FIG. 3 is a cross-sectional view of the exemplary embodiment illustrated in FIG. 2.

FIG. 4 is a perspective view of a cell phone according to an exemplary embodiment of the present invention.

FIG. 5 is a perspective view of a notebook computer according to an exemplary embodiment of the present invention.

### DETAILED DESCRIPTION OF THE INVENTION

The invention will now be described in connection with the associated figures. FIG. 1 illustrates an exemplary embodiment of an insulating structure 10. In this embodiment, insulating structure 10 includes an insulating material 11 and a heat spreading material 12.

Insulating material 11 is any material that inhibits heat from being conducted in the Z-direction (see figures). Preferably, insulating material 11 has a Z-direction thermal conductivity of less than air, or about 25 miliWatts per meter degree Kelvin (mW/m-K) but may be higher, depending upon the application requirements. Also preferably, the insulating material 11 is less than about 2 mm thick and is compressible by at least 10% with a pressure of about 50 psi. Insulating material 11 compositions include versions that are designed to operate in a vacuum (also called vacuum insulation panels), and versions that are designed to operate at atmospheric pressure (also called non-vacuum insulation panels). Appropriate insulating material 11 alternatives include:
(a) Vacuum insulation panels comprising macroporous foams (defined herein as foams with average pore sizes greater than about 10 microns), or similar materials, and evacuated to a pressure of preferably less than about 0.1 mbar;
(b) Vacuum insulation panels comprising mesoporous foams (defined herein as foams with average pore sizes between about 0.1 microns and about 10 microns), or similar materials, and evacuated to a pressure of preferably less than about 10 mbar, and more preferably less than about 0.1 mbar;
(c) Vacuum insulation panels comprising aerogels, fumed silica, microporous foams (defined herein as foams with average pore sizes about 0.1 microns or less), or similar materials, and evacuated to a pressure of preferably less than about 10 mbar; or
(d) Non-vacuum insulation panels comprising aerogels, fumed silica, microporous foams, or similar materials, and used at atmospheric pressure (1013 mbar).

Of the above, (a) and (c) typically have thermal conductivities of about 5 mW/m-K or less, and (d) typically have thermal conductivities of about 25 mW/m-K or less. The materials used in (c) or (d) have average pore sizes approximately on the order of the mean free path of an air molecule at atmospheric pressure or less (on the order of 0.1 microns or less) and preferably a porosity of greater than about 90%. The small pore size minimizes the heat conduction by air molecules and the high porosity minimizes the heat conduction by the solid component.

In a preferred embodiment, insulating material 11 is comprised of aerogel particles in combination with a binder. The binder is preferably PTFE. Such aerogel/PTFE insulating materials are described, for example, in U.S. application Ser. No. 10/706,777, titled “Aerogel/PTFE Composite Insulating Materials,” which is incorporated herein by reference for its teachings on areogel/PTFE insulating materials. Alternatively the binder is polyurethane, polyethylene, or any material capable of holding aerogel particles together in a useable form.

The heat spreading material 12 is any material that is highly thermally conductive in the XY-direction. Heat spreading material 12 may be in any of the following alternative forms: a coating provided on at least a portion of the insulating material, or a separate layer or layers laminated or otherwise joined together with the insulating material. Preferably, heat spreading material 12 has an XY-direction thermal conductivity of at least 100 W/m-K and is comprised of a highly conductive metal such as copper or aluminum (or alloys, thereof), or most preferably, a material such as graphite. Such graphite heat spreading materials are available commercially from Graftech International, Ltd. under the tradename eGraf® Spreadershield™. Heat spreading material 12 and insulating material 11, in combination, function to reduce hot-spots surprisingly more effectively than known devices by distributing the heat over a larger area of the insulating structure 10 while inhibiting the heat from being transferred in the Z-direction.

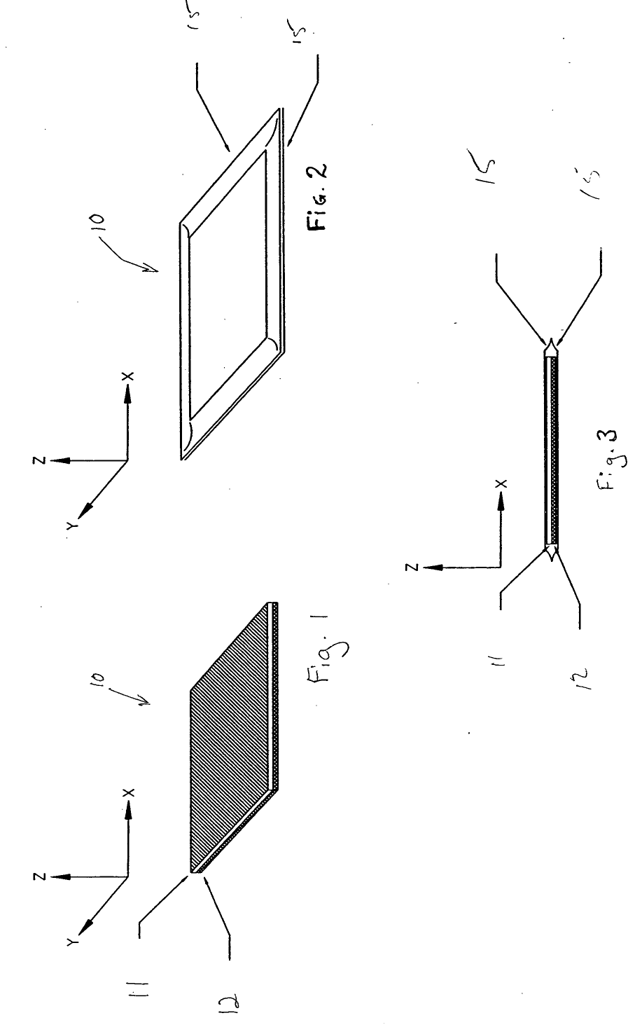

Insulating structure 10 optionally further includes a film layer 15 disposed on one or both sides of insulating structure 10. As shown in the exemplary embodiment of FIG. 2 and FIG. 3, film layers 15 are disposed on both sides of insulating structure 10. Film layers 15 may be used to encapsulate the insulating material 11, or a composite of the insulating material 11 and heat spreading material 12, and may provide, for example, electrical isolation, a convenient means to mechanically keep the composite together, a way to seal the insulating material 11 under vacuum (i.e. to form a vacuum insulation panel), or a way to prevent dusting or particulation from the insulating material 11 or heat spreading material 12. In applications where the insulating material 11 is sealed under vacuum, film layers 15 are preferably gas impermeable. In applications where the insulating material 11 is not sealed under vacuum, film layers 15 do not need to be gas impermeable, and preferably include PTFE, or more preferably, expanded PTFE. The insulating material 11, heat spreading material 12, and film layers 15 are preferably adjacent to each other, and may be laminated or otherwise joined together with the use of an adhesive (not shown), or by other mechanical means to form the insulating structure 10.

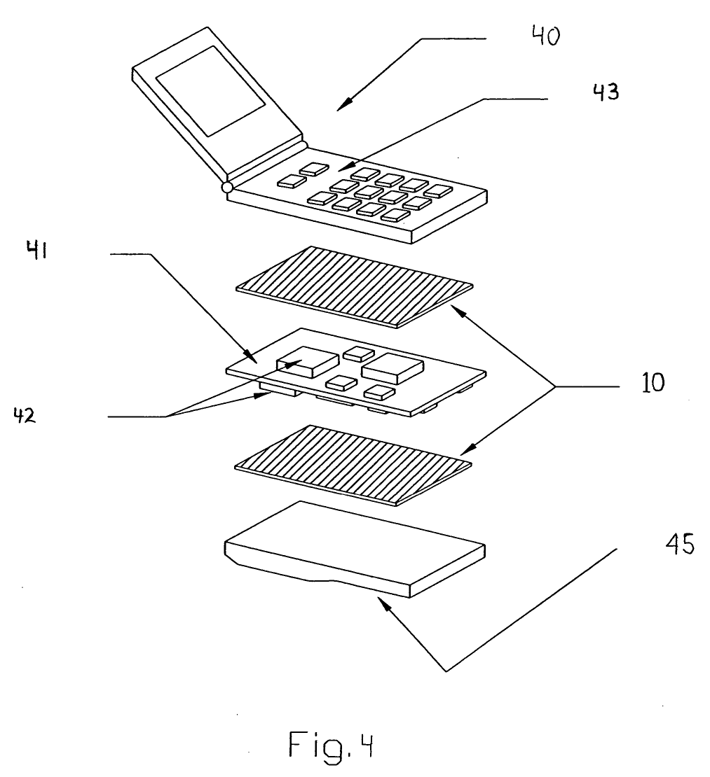

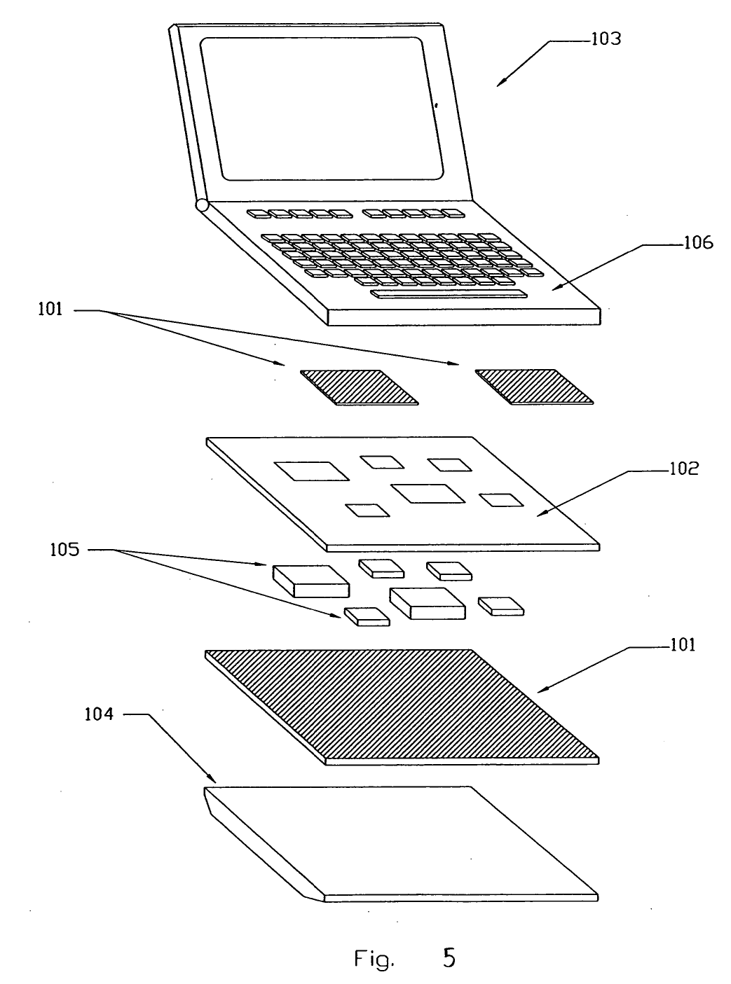

FIG. 4 is an exemplary embodiment of a cellular phone 40 having at least one insulating structure 10 (two insulating structures 10 are shown in the illustrated embodiment). Insulating structures 10 in this embodiment are placed between a printed circuit board 41 with heat generating components 42 (such as a power amplifier, multimedia processor, and the like) and a keypad enclosure surface 43. Keypad enclosure surface 43 of cellular phone 40 is often in contact with a user's face (not shown), so it is important to minimize hot-spots in this area. An insulating structure 10 is also be placed in this embodiment between a printed circuit board 41 with heat generating components 42 and a back enclosure surface 45 of the cellular phone that may contact a user's hand (not shown), again an area where it is important to minimize hot-spots. In other embodiments (not shown), insulating structures 10 are located external to keypad enclosure surface 43 and back enclosure surface 45. For example, insulating structure 10 may be located on at least a portion of enclosure outer surface 45 that is designed to be in direct contact with a user's hand.

In FIG. 5, a notebook computer is illustrated having insulating structures 101 that are similar in construction to insulating structure 10. An insulating structure 101 may be placed between a printed circuit board 102 with heat generating components 105 such as a CPU (central processing unit), hard-disk drive, or a GPU (graphics processing unit) and a bottom enclosure surface 104 that is, for example, designed to be in contact with the user's lap (not shown). Alternatively, insulating structures 101 may be placed between a printed circuit board 102 with heat generating components 105 and a top enclosure surface 106 that is, for example, designed to be in contact with the user's palm (not shown). In another embodiment (not shown), an insulating structure 101 may be located external to at least a portion of the bottom enclosure surface 104 or top enclosure surface 106 that is designed to be in direct contact with a user's lap, palm, or other portion of the body.

In another embodiment, a portable electronic device comprises an electronic device, such as a cell phone or computer, and carrying case, wherein the carrying case comprises an insulating structure. Preferably, the insulating structure may be located between multiple layers of a carrying case.

Advantageously, insulating structures with low Z-direction thermal conductivity may be formed that are sufficiently thin to be incorporated into such devices, or external to such devices, without any increase or without any significant increase in the overall dimensions of the physical enclosure. Preferred insulating structures for use in electronic devices comprise insulating materials of the present invention and are in the form of a tape or sheet, die-cut or otherwise formed to a dimensional size to fit readily into unused space in the device.

1. An insulating structure comprising
an insulating material, and
a heat spreading material.

2. The insulating structure of claim 1 wherein the insulating material has a Z-direction thermal conductivity of less than or equal to about 25 mW/m-K.

3. The insulating structure of claim 2 wherein the insulating material is evacuated to a pressure of less than one atmosphere.

4. The insulating structure of claim 1 wherein the heat spreading material has an XY-direction thermal conductivity of greater than about 100 W/m-K.

5. The insulating structure of claim 1 wherein the insulating material comprises aerogel particles.

6. The insulating structure of claim 1 wherein the insulating material comprises a polytetrafluoroethylene binder.

7. The insulating structure of claim 1 wherein the heat spreading material comprises graphite.

8. The insulating structure of claim 1 wherein the heat spreading material comprises aluminum or copper.

9. The insulating structure of claim 1, wherein the heat spreading material is in the form of a coating on at least a portion of the insulating material.

10. The insulating structure of claim 1, wherein the heat spreading material is in the form of at least one separate layer laminated or otherwise joined together with the insulating material.

11. The insulating structure of claim 1 further comprising
at least two film layers,
wherein the film layers encapsulate the insulating material.

12. The insulating structure of claim 11
wherein the insulating material is evacuated to a pressure of less than one atmosphere.

13. The insulating structure of claim 1 further comprising
at least two film layers,
wherein the film layers encapsulate the insulating material and heat spreading material.

14. The insulating structure of claim 13
wherein the insulating material and heat spreading material are evacuated to a pressure of less than one atmosphere.

15. A portable electronic device comprising
at least one heat generating component,
an enclosure surface adjacent said at least one heat generating component, and
an insulating structure disposed between said at least one heat generating component and said enclosure surface;
wherein the insulating structure comprises an insulating material and a heat spreading material.

16. The portable electronic device of claim 15 wherein the insulating material has a Z-direction thermal conductivity of less than or equal to about 25 mW/m-K.

17. The insulating structure of claim 16 wherein the insulating material is evacuated to a pressure of less than one atmosphere.

18. The portable electronic device of claim 15 wherein the heat spreading material has a XY-direction thermal conductivity of greater than about 100 W/m-K.

19. The portable electronic device of claim 15 wherein the insulating material comprises aerogel particles.

20. The portable electronic device of claim 15 wherein the insulating material comprises a polytetrafluoroethylene binder.

21. The portable electronic device of claim 15 wherein the heat spreading material comprises graphite.

22. The portable electronic device of claim 15 wherein the heat spreading material comprises aluminum or copper.

23. The portable electronic device of claim 15, wherein the heat spreading material is in the form of a coating provided to at least a portion of the insulating material.

24. The portable electronic device of claim 15, wherein the heat spreading material is in the form of at least one separate layer laminated or otherwise joined together with the insulating material.

25. The portable electronic device of claim 15 further comprising
at least two film layers,
wherein the film layers encapsulate the insulating material.

26. The portable electronic device of claim 15 further comprising
at least two film layers,
wherein the film layers encapsulate the insulating material and heat spreading material.

27. The portable electronic device of claim 15 wherein the portable electronic device is a notebook computer.

28. The portable electronic device of claim 15 wherein the portable electronic device is a cell phone.

29. A method of reducing the temperature at hot-spots of a portable electronic device comprising the steps of providing a portable electronic device having at least one heat generating component and an enclosure having a surface, and placing an insulating structure comprising an insulating material and a heat spreading material between the heat generating component and the enclosure, thereby preventing or delaying the transfer of heat from the heat generating component to at least a portion of the enclosure surface.

30. An insulating structure comprising
an insulating material comprising aerogel particles and a polytetrafluoroethylene binder, said insulating material having a Z-direction thermal conductivity of less than or equal to about 25 mW/m-K at atmospheric conditions, and said insulating material being less than about 2 mm thick, compressible by at least 10% with a pressure of about 50 psi; and
a heat spreading material having an XY-direction thermal conductivity of greater than about 100 W/m-K at atmospheric conditions.
